(19) United States
(12) Patent Application Publication
(10) Pub. No.: US 2024/0243170 A1
(43) Pub. Date: Jul. 18, 2024

(54) MEMBRANE SEMICONDUCTOR COMPONENT AND METHOD FOR PRODUCING THE SAME

(71) Applicant: Robert Bosch GmbH, Stuttgart (DE)

(72) Inventors: Christian Huber, Ludwigsburg (DE); Stefan Regensburger, Renningen (DE)

(21) Appl. No.: 18/557,201

(22) PCT Filed: Apr. 20, 2022
(86) PCT No.: PCT/EP2022/060320

§ 371 Date: Jan. 19, 2024

(30) Foreign Application Priority Data
Apr. 27, 2021 (DE) 10 2021 204 159.0

(51) Int. Cl. H01L 29/06; H01L 21/78; H01L 29/20; H01L 29/417; H01L 29/66; H01L 29/78

(52) U.S. Cl. CPC H01L 29/0657; H01L 21/78; H01L 29/41766; H01L 29/66712; H01L 29/7813; H01L 29/2003

(57) ABSTRACT

A membrane semiconductor component which has an outer region and a membrane region. At least part of a substrate is disposed in the outer region. The substrate is structured such that a backside cavity is configured in the membrane region. The backside cavity is free of substrate. At least one active region is disposed in the membrane region, and the active region comprises at least one pn transition. At least one target contact point for membrane semiconductor component-external contacting is disposed on or above the substrate in the outer region. The target contact point has an electrically conductive structure, which is coupled to the active region.

### BACKGROUND INFORMATION

Transistors based on gallium nitride (GaN) make it possible to implement transistors that have lower on-resistances with simultaneously higher breakdown voltages than the comparable silicon-based or silicon carbide-based components.

GaN transistors are known primarily from so-called high-electron mobility transistors (HEMTs), in which the current flows laterally on the upper side of the substrate through a two-dimensional electron gas which forms the transistor channel. Such lateral components can be produced by heteroepitaxy of the functional GaN layers on silicon wafers. For high breakdown voltage with low on-resistance per unit area, however, vertical components in which the current flows from the front of the substrate to the back of the substrate are more advantageous, both in terms of size and the electric field distribution inside the component. Such a component cannot be produced directly by heteroepitaxial GaN layers on silicon (Si), because insulating intermediate layers (a so-called buffer) are needed to adapt the lattice mismatch between GaN and Si and to reduce the substrate curvature.

The buffer itself is mechanically tensioned in such a way that it just compensates the tensioning of the GaN layers at room temperature. However, since the buffer is an insulator, the buffer prevents the flow of current from the front of the substrate to the back of the substrate.

Native GaN substrates, on which the required additional epitaxial GaN layers of the component can be grown without the need for an insulating buffer, are available as well. However, such GaN substrates are small (typically 50 mm in diameter) and expensive.

To reduce the transistor price per surface element, it can be advantageous to use the available heteroepitaxial GaN layers on large silicon substrates. For this purpose, vertical components (trench MOSFET, pn diode) are available, in which the silicon substrate and the insulating buffer under the component are selectively removed, which creates a backside trench in order to thus be able to contact the backside of the drift zone of the component directly. FIG. 1 shows the basic structure of such a component 1 with an insulating buffer and a backside trench (here on the basis of a trench MOSFET). The backside trench can also be referred to in the following as a backside cavity or backside aperture.

As shown in FIG. 1, III-V nitride semiconductor layers (GaN with the exception of the buffer) are epitaxially grown on the silicon substrate 61 or generally following the carrier substrate: the insulating buffer 13, a highly doped contact semiconductor layer with n-conductivity 14, the low-doped n-conductive drift layer 15, a p-conductive body layer 16 and a highly doped n-conductive source contact layer 17.

A trench, the side walls and base of which are separated from the gate electrode 21 by a gate dielectric material 22, passes through the source contact layer 17 and the body layer 16. The source contact layer 17 and the body layer 16 are contacted by a source electrode 41, which is separated from the gate electrode 21 by an insulation layer 31. On the back side, the silicon substrate 61 and the buffer 13 are removed by a backside trench 51 which ends in the highly doped contact semiconductor layer with n-conductivity 14. This is contacted by a backside drain electrode 52. During operation, a conductive channel is formed in the body layer 16 by applying a gate voltage to the gate electrode 21, through which a flow of current from the source electrode 41 to the drain electrode 52 is made possible.

For the sake of simplicity, FIG. 1 shows a transistor comprising three cells, i.e. three repeating structures. In a real transistor, a large number of such cells are typically present and are therefore effectively connected in parallel. Typical active surfaces are in the range of a few square millimeters; the remaining GaN layers are a few micrometers thick. The drain electrode 52 can be made of a plurality of metallic layers.

FIG. 2A and FIG. 2B show schematic cross-sectional views of a method commonly used in the related art for singulating a wafer comprising a plurality of transistor chips into individual chips. FIG. 2A shows the transistor chip prior to singulation and FIG. 2B shows the transistor chip after singulation. After singulation, the transistor chips can be picked up off a carrier 71 to be further processed by means of conventional methods of assembly and connection technology. For this purpose, markings, so-called dicing trenches 72, are provided on the front in a region outside the active transistor region (for example the region that includes the source electrode 41 and/or the backside trench 51). As shown in FIG. 2A, these markings can be an etching in which portions of the insulation layer 31 have been removed. Alternatively, additional layers are provided as markings, for example in the form of a metallization that is not electrically connected to the source electrode 41.

The marking of the dicing trench 72 serves as a marker for the subsequent dicing or singulation process. For this purpose, the wafer 61 is placed onto a so-called dicing foil 71 (dice tape or bluetape), which is stretched in a frame. The wafer 61 is subsequently singulated along the dicing trenches 72 using a diamond-coated dicing blade, so that a wider dicing line is created and singulated chips remain on the dicing foil 71 and can then be picked up off the dicing foil 71. In such a dicing process, the same dicing line can also be cut repeatedly to different depths or different dicing blades can be used for different depths. Alternatively, the chips are singulated in a conventional manner by means of a laser, wherein the separation is carried out by means of the laser or using a so-called stealth dicing process, in which the laser is used to create a type of preset breaking point at which the chips break in two during a subsequent lateral expansion of the dicing foil 71.

Dicing or laser processes are serial processes, because the tracks have to be cut/written one after the other. For larger wafer diameters, however, the process time and thus also the costs increase.

### SUMMARY

A membrane semiconductor component having features of the present invention, on the other hand, has an advantage of reducing costs when singulating the membrane semiconductor components. The thickness to be cut for singulating the membrane semiconductor component is clearly reduced by the second backside cavity in the outer region. This makes it possible to achieve laterally narrower dicing lines, as a result of which less wafer area is lost to dicing and costs can be saved.

The membrane semiconductor component can furthermore enable dicing-free singulation processes. The singulation of membrane semiconductor components can thus be carried out in a safe, reliable and quicker manner. Dicing-free processes can be based on breaking by lateral expansion or pressurization of a target separation point, for example.

The membrane semiconductor component can moreover also be used to reduce or avoid so-called backside chipping. Backside chipping is a breakout of the dicing trench on the back side of the wafer that occurs in a classic dicing process.

Further developments of the aspects and advantageous embodiments of the membrane semiconductor component of the present invention are disclosed herein.

### BRIEF DESCRIPTION OF THE DRAWINGS

Embodiments of the present invention are shown in the figures and are explained in more detail in the following.

FIG. 1 shows a schematic illustration of a membrane transistor of the related art.

FIG. 2A and FIG. 2B show schematic illustrations of a vertical field effect transistor of the related art.

FIG. 3A to FIG. 8 show schematic illustrations of a membrane semiconductor component according to various aspects of the present invention.

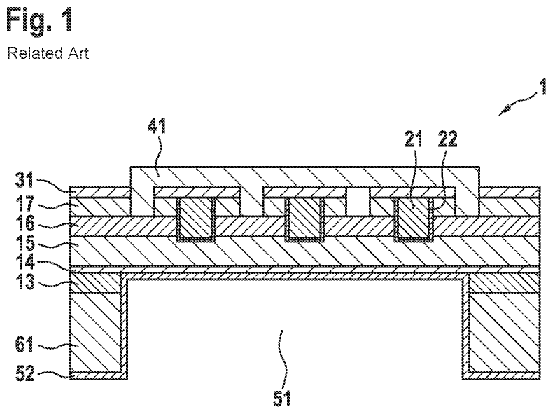

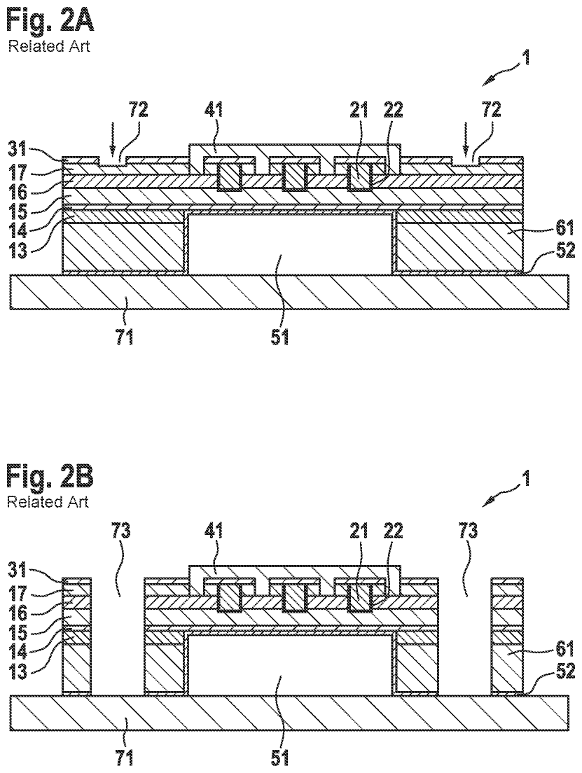

In the following detailed description, reference is made to the figures, which form part of this description and which, for illustrative purposes, show specific embodiment examples in which the present invention can be practiced. It goes without saying that other embodiment examples can be used and structural or logical modifications can be made without departing from the scope of protection of the present invention. It goes without saying that the features of the various embodiment examples described here can be combined with one another unless specifically stated otherwise. The following detailed description is therefore not to be construed in a limiting sense. In the figures, identical, or similar elements are provided with identical reference signs when appropriate.

In the following description, various aspects and embodiments are described using the example of a trench MOSFET. However, it goes without saying that the possibility of providing such conductive access to the backside of a drift zone by means of a backside trench is not limited to a trench MOSFET, so that this technology can in principle be used to manufacture any vertical power semiconductor components, such as Schottky diodes, pn diodes, vertical diffusion MOSFETS (VDMOS), current apertured vertical electron transistors (CAVETs), vGroove vertical high electron mobility transistors (vHEMTs) or fin field effect transistors (FinFETs).

### DETAILED DESCRIPTION OF EXAMPLE EMBODIMENTS

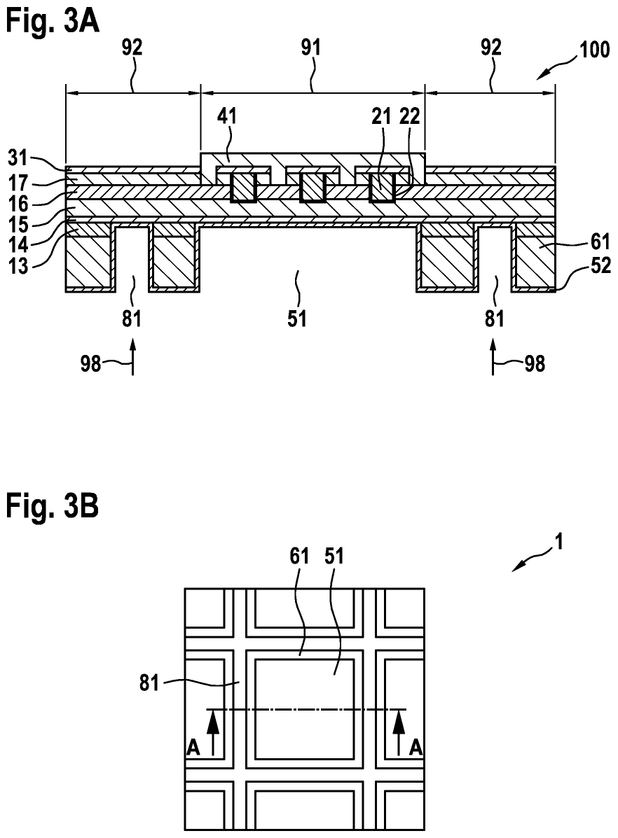

FIG. 3A shows a schematic cross-sectional view of a membrane semiconductor component 100 according to various example embodiments of the present. FIG. 3B shows a schematic view of the membrane semiconductor component 100 shown in FIG. 3A. The dashed line in FIG. 3B shows the region depicted in FIG. 3A. The membrane semiconductor component 100 comprises a (second) backside cavity 81. The second backside cavity 81 is also referred to in the following as the dicing cavity 81. The (first) backside cavity 51 is disposed underneath or substantially underneath the active region of the membrane semiconductor component 100 for the drain contact 52. In other words: the first backside cavity 51 is disposed in the region in which switchable transistor channels are configured.

The dicing cavity 81 is disposed outside the active region, for example in the outer region 92 outside the membrane region 91.

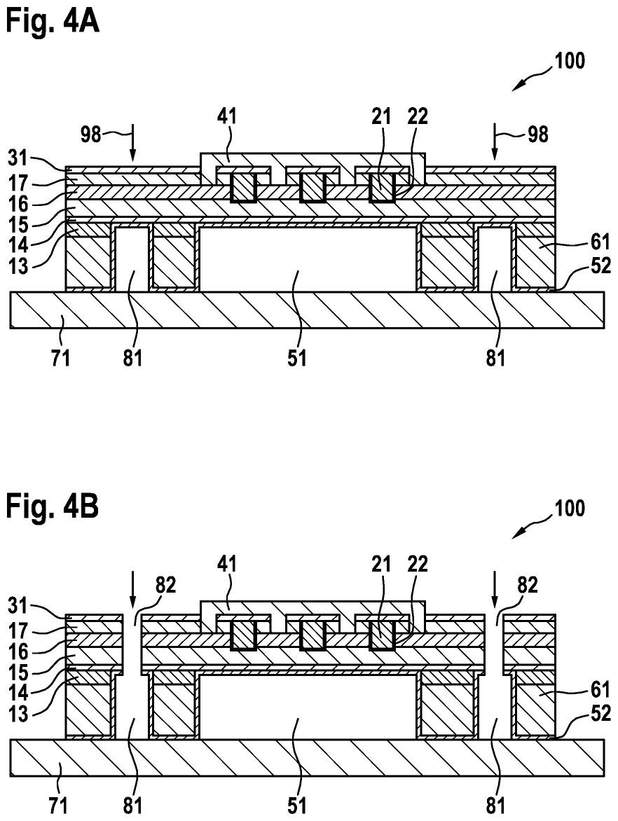

The dicing cavity 81 can be disposed peripherally around the active region 91 as shown in FIG. 4A and FIG. 4B. The dicing cavity 81 can be configured in the same process step as the backside cavity 51, for example. The dicing cavity 81 can, for instance, be created using a dry chemical plasma etching process (for example referred to as deep reactive ion etching (DRIE)), without generating additional costs. Structures that can be etched in the same process step when plasma etching do not generate any additional costs.

In a variety of embodiments, the configuration of the second backside cavity 81 or the dicing cavity 81 can be carried out using an etching process. The etching process can be a wet chemical etching process or a dry chemical etching process, for example DRIE. The second backside cavity 81 can have the shape of a trench or a blind hole with a side wall in the substrate 61, for instance. In other words: the second backside cavity 81 can be a blind hole, a plurality of spaced-apart blind holes, a trench, or a combination thereof, in the substrate 61. The side wall of the blind hole or trench in the substrate 61 can be the boundary of the second backside cavity 81 (optionally covered by the drain electrode 52). The side wall, for example the substrate 61 and/or the drain electrode 52 on the surface of the side wall, can have a ripple structure, for example a periodic ripple pattern. The periodic ripple pattern can, for instance be produced using a dry chemical etching process, for example DRIE. The second backside cavity 81 can thus clearly be free of dicing marks.

Alternatively or additionally, the separation of the target separation point 98 can be carried out using an etching process. The etching process can be a wet chemical etching process or a dry chemical etching process, for example DRIE. When separating the target separation point using an etching process, one or more layers 13, 14, 15, 16, 17, 31 on or above the second backside cavity 81 are removed by the etching process as described in more detail in the following.

The dicing cavity 81 can have a width, for example a lateral dimension, that is in a range of about 20 μm to about 100 μm.

With a narrow dicing cavity 81, the chip area needed for the target separation point 98 is small.

The etching speed can decrease as the aspect ratio of the structure to be etched increases. In the case of narrow dicing cavities 81, an additional and/or extended etching process may therefore be necessary to create the backside cavity 51.

As not shown in FIG. 3A and FIG. 3B, the substrate 61, for example a wafer, can be stabilized on the front side during singulation on a temporary support, for example a carrier wafer, for instance by temporary bonding. This may be necessary if there is no continuous connection between the individual chips via the silicon substrate 61 as a result of the dicing cavity 81. For example, if the thickness of the GaN layers and the other front-side layers is only a few to a few tens of micrometers.

In other words: the membrane semiconductor component 100 has an outer region 92 and a membrane region 82. At least part of a substrate 61 is disposed in the outer region 92. The substrate 61 is structured such that a first backside cavity 51 is configured in the membrane region 82. The first backside cavity 51 is free of substrate 61. At least one active region is disposed in the membrane region 82. Depending on the application, the active region can comprise at least one control electrode 21, a source electrode 41 and/or a pn transition, for example. The membrane semiconductor component 100 further includes a target separation point 98, which comprises a second backside cavity 81 in the outer region 82. The second backside cavity 81 is free of substrate 61.

A filling material can be disposed in the first backside cavity 51. The filling material can be electrically and thermally conductive. The second backside cavity 81 is free of filling material.

The drain electrode 52 can be disposed in the first backside cavity 51 and in the second backside cavity 81. The drain electrode 52 can alternatively be disposed in the first backside cavity 51. The second backside cavity 81 can be free of the drain electrode 52. The target separation point 98 can be configured such that it is free of metal.

The target separation point 98 can further comprise one or more layers 13, 14, 15, 16, 17, 31 on or above the second backside cavity 81. The one layer 13, 14, 15, 16, 17, 31 or the multiple layers 13, 14, 15, 16, 17, 31 can each comprise or be made of a material that is optically transparent or translucent.

In other words: a membrane semiconductor component structure (not shown) can include a first membrane semiconductor component 100 and a second membrane semiconductor component 100 having a common substrate 61. Each of the first and the second membrane semiconductor component 100 can have a membrane region 82 and an outer region 92 between the first and the second membrane semiconductor component 100. The substrate 61 is structured such that a respective first backside cavity 51 is configured in the membrane region 82 of the first and the second membrane semiconductor component 100, wherein the first backside cavity 51 is free of substrate 61 and wherein at least one respective active region is disposed in the membrane region 82 of the first and the second membrane semiconductor component 100 and the active region comprises at least one control electrode 21. The membrane semiconductor component structure has a target separation point 98 which comprises a second backside cavity 81 in the outer region 82 between the first and the second membrane semiconductor component 100, wherein the second backside cavity 81 is free of substrate 61.

FIG. 4A and FIG. 4B show schematic cross-sectional views of the membrane semiconductor component 100 prior to (FIG. 4A) and after (FIG. 4B) singulation in a dicing or chip singulation process according to various embodiments.

The drawing shows that the wafer 61 with the membrane semiconductor components 100 which are spaced apart by dicing cavities 81 is placed on a dicing tape 71. A not-depicted temporary carrier substrate, which can optionally be applied to the front, can be removed.

Depending on the application, the dicing cavities 81 can be visually detectable from the front side. The gallium nitride layers 14, 15, 16 17 and the insulation layer 31 can be configured such that they are substantially transparent in the visible spectral range, for example. The dicing cavities 81 can thus create a visual contrast to the substrate 61. The dicing cavity 81 can therefore serve as a position marker.

The layers 14, 15, 16, 17, 31, which remain above the dicing cavity 81 and which can have a thickness of a few micrometers, can be cut using a conventional dicing process, for example using a dicing blade or a laser process, as a flat cut (shown by the arrow in FIG. 4B). The cutting region can have the same lateral dimension as the dicing cavity 81 or a different lateral dimension than the dicing cavity 81, for example narrower or wider than the dicing cavity 81.

A cut having a small thickness (vertical dimension), as can be achieved using the dicing cavity 81, reduces the risk of so-called backside chipping during production of the membrane semiconductor component 100. The small thickness of the layers 14, 15, 16, 17, 31 above the dicing cavity 81 makes it possible for the repeated traversing of each dicing path with different strokes or different dicing blade diameters, which is commonly used to reduce backside chipping, to become optional. The membrane semiconductor component 100 can thus simplify the dicing process. As a result, the process time and costs of dicing can be reduced.

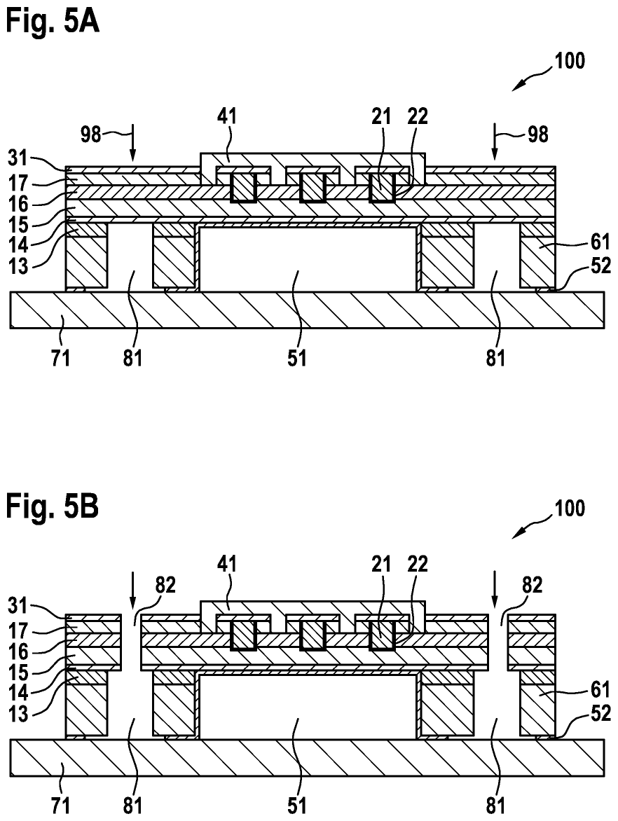

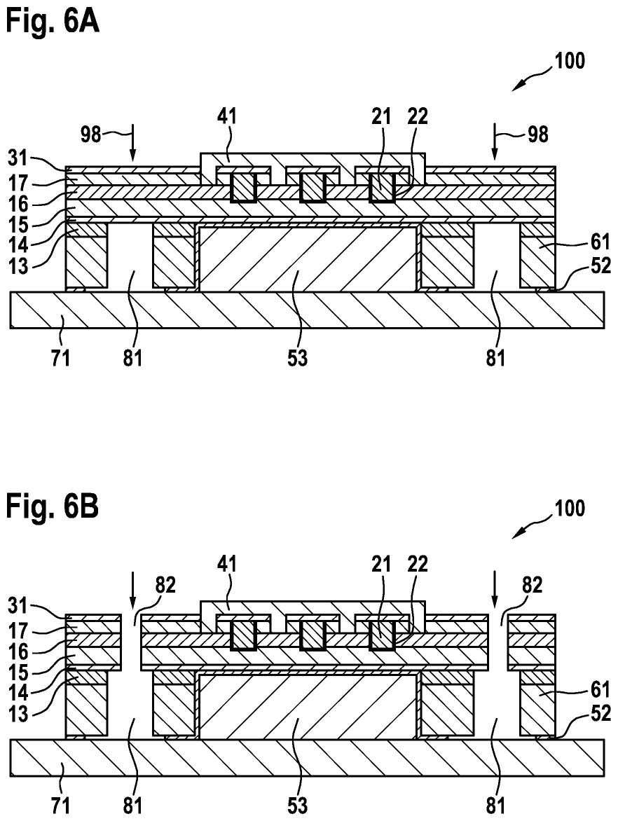

FIG. 5A-5B and FIG. 6A-6B show schematic cross-sectional views of the membrane semiconductor component 100 prior to (FIG. 5A, FIG. 6A) and after (FIG. 5B, FIG. 6B) singulation in a dicing or chip singulation process according to various embodiments. In various embodiments, the membrane semiconductor component 100 can be configured such that the region of the dicing cavity 81 remains free of the drain electrode 52 as shown in FIG. 5A-FIG. 6B.

Compared to semiconductor materials, metals can be relatively soft materials. The dicing blade of a wafer dicing saw can therefore become soiled, for example smeared, during singulation. Also, if the thickness of the semiconductor layers 14, 15, 16, 17 is small, there is a risk of creating an electrical short circuit between the drain electrode 52 on the backside and the source electrode 41 and/or the gate electrode 21 on the front side when cutting through the drain electrode 52. In various embodiments, the drain electrode 52 can be removed from the region of the dicing cavity 81, or the drain electrode 52 can be structured such that the region of the dicing cavity 81 and/or the region laterally around the dicing cavity 81 remains free of the metal of the backside contact, for example the drain electrode 52, and/or the front side contact, for example the source electrode 41 and/or the gate electrode 21. The structured configuration of the drain electrode 52 can be implemented using a shadow mask process in a sputtering process, for example. The structured configuration, for example of the drain electrode 52, can alternatively be implemented by selectively etching the drain electrode 52 in the region of the dicing cavities 81. Since there is consequently no metal in the region of the dicing cavities 81, there is therefore no risk of a short circuit and the wear on the dicing blade is reduced.

In various embodiments, the membrane semiconductor component 100 can be configured such that the first backside cavity 51 is partly or entirely filled with a filling material 53, as shown in FIG. 6A-FIG. 6B. This can enable low electrical and thermal drain resistance as well as a high stability of the wafer and the final chips. In various embodiments, the dicing cavities 81 can remain free of filling material 53.

Selective filling of the backside cavity 51 with filling material 53 can be carried out by filling with a metal paste, for example copper, a solder or selective thickening by electroplating (by lithographic masking or selective application of the electrical seed layer, for example.

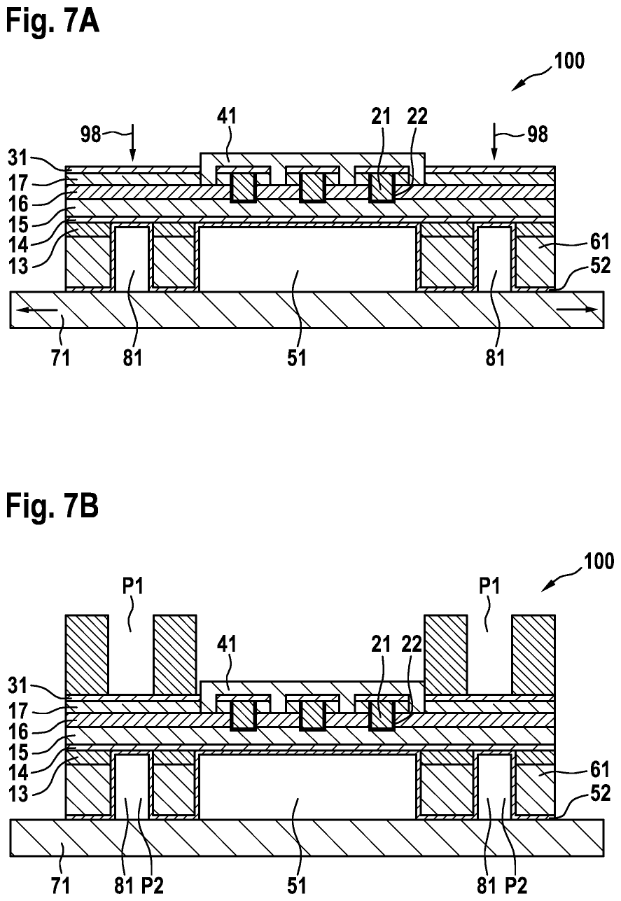

FIG. 7A and FIG. 7B show schematic cross-sectional views of the membrane semiconductor component 100 in chip singulation processes other than the dicing process according to various embodiments. As an alternative to the dicing process, the singulation of the membrane semiconductor components can be carried out by breaking the layers above the second backside cavity 81. For this purpose, the membrane semiconductor component 100 can be disposed on a laterally deformable carrier 71, for example a so-called dicing tape 71, that is laterally deformed, for example laterally expanded, for singulation (shown in FIG. 7A by means of the outward directed arrows 99). The deformation of the carrier 71 causes the layers 13, 14, 15, 16, 17, 31, which can have a thickness of a few micrometers, to break above the second backside cavity 81. The membrane semiconductor component 100 can then be taken off the carrier 71 in singulated form.

In various embodiments, the first backside cavity 51 can be filled with a filling material (not shown, but see FIG. 6A, FIG. 6B, for example) to mechanically stabilize the active region of the membrane semiconductor component (also referred to as the membrane region) during lateral expansion of the carrier 71. The second backside cavity 81 can then remain free of filling material 53, which simplifies singulation.

In another process, shown in FIG. 7B, a pressure P1, which differs from the pressure P2 between the second backside cavity 81 and the carrier 71, can be selectively applied in the region above the second backside cavity 81. The pressure difference (|P1−P2|) can be a positive pressure (P1>P2) or a negative pressure (P1<P2). The pressure difference can be used to cut the layers 13, 14, 15, 16, 17, 31 above the second backside cavity 81, as a result of which the membrane semiconductor components 100 can be singulated.

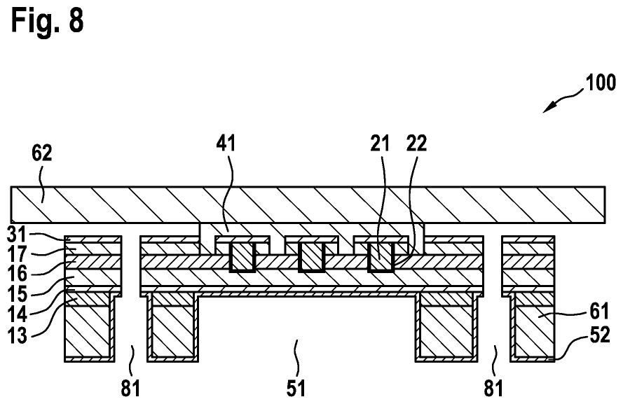

FIG. 8 shows a schematic cross-sectional view of the membrane semiconductor component 100 in a chip singulation process other than the dicing process according to various embodiments. The membrane semiconductor component 100 can be singulated while the membrane semiconductor component 100 is bonded to the carrier wafer 62 on the front side. This can be carried out with a dedicated wafer dicing saw in the dicing cavity 81, for example, or alternatively with a dry or wet chemical etching process in the second backside cavity 81. This allows the remaining layers above the second backside cavity 81 to be cut, creating a gap 82. This enables increased stability, because the membrane semiconductor component 100 is connected to the carrier wafer 62.

The width of the break edges can be set via the aspect ratio of the dry or wet chemical etching for the silicon substrate 61 and the gallium nitride-containing layers 14, 15, 16, 17 and the insulation layer 31, for instance. Depending on the application, the membrane semiconductor component can cause the width of the break edges to be predetermined only by the aspect ratio of a dry chemical etching or a wet chemical etching of the etching for the silicon substrate 61 and the gallium nitride-containing layers 14, 15, 16, 17 and the insulation layer 31. The width of the break edge can thus be independent of the width of an optionally usable dicing blade. Depending on the application, there may be a cost advantage in various embodiments, because time-consuming sequential dicing steps can be omitted or the number thereof can be reduced. The second backside cavity 81 can also be configured in parallel or at the same time for the entire wafer. Depending on the process parameters, backside chipping can be reduced or avoided.

The temporary connection of the membrane semiconductor component 100 to the carrier wafer 62 can be selectively removed by means of a laser through the carrier wafer 62 as the membrane semiconductor component 100 is being picked up off the carrier wafer 62, or can be carried out across the entire surface using another commonly used method. The backside of the substrate 61 can alternatively be placed on a carrier 71 prior to debonding from the carrier wafer 62 and the membrane semiconductor component 100 can then be removed from the carrier wafer 62. The individual membrane semiconductor components 100 can then be taken off the carrier 71.

The embodiments described and shown in the figures are selected merely as examples. Different embodiments can be combined with one another completely or with respect to individual features. One embodiment can also be supplemented by features of another embodiment. The described method steps can furthermore be repeated and carried out in an order other than that described. The present invention is in particular not limited to the specified method.

1-13. (canceled)

14. A membrane semiconductor component, comprising:
an outer region and a membrane region, wherein at least part of a substrate is disposed in the outer region, wherein the substrate is structured such that a first backside cavity is configured in the membrane region, wherein the first backside cavity is free of the substrate, and wherein at least one active region is disposed in the membrane region, and the active region includes at least one control electrode and a target separation point which includes a second backside cavity in the outer region, wherein the second backside cavity is free of the substrate.

15. The membrane semiconductor component according to claim 14, further comprising:
a filling material which is disposed in the first backside cavity, wherein the filling material is electrically and thermally conductive, and wherein the second backside cavity is free of the filling material.

16. The membrane semiconductor component according to claim 14, further comprising:
a drain electrode disposed in the first backside cavity and in the second backside cavity.

17. The membrane semiconductor component according to claim 14, further comprising:
a drain electrode disposed in the first backside cavity, wherein the second backside cavity is free of the drain electrode.

18. The membrane semiconductor component according to claim 14, wherein the target separation point is configured such that it is free of metal.

19. The membrane semiconductor component according to claim 14, wherein the target separation point further includes one or more layers on or above the second backside cavity, wherein the one or more layers includes a material that is optically transparent or translucent.

20. The membrane semiconductor component according to claim 14, wherein the second backside cavity is a trench or a blind hole with a side wall in the substrate, wherein the side wall has a ripple structure.

21. The membrane semiconductor component according to claim 20, wherein the ripple structure is a periodic ripple pattern.

22. The membrane semiconductor component according to claim 14, wherein the second backside cavity is free of dicing marks.

23. A membrane semiconductor component structure, comprising:
a first membrane semiconductor component and a second membrane semiconductor component, the first and second membrane semiconductor components having a common substrate;
wherein each of the first and the second membrane semiconductor component includes a membrane region and an outer region disposed between the first membrane semiconductor component and the second membrane semiconductor component, wherein the substrate is structured such that a respective first backside cavity is configured in the membrane region of the first membrane semiconductor component and in the membrane region of the second membrane semiconductor component, wherein the first backside cavity is free of the substrate, and wherein at least one respective active region is disposed in the membrane region of the first membrane semiconductor component and in the membrane region of the second membrane semiconductor component, and the active region includes at least one control electrode; and
wherein a target separation point which includes a second backside cavity in the outer region between the first membrane semiconductor component and the second membrane semiconductor component, and wherein the second backside cavity is free of the substrate.

24. A method for producing a membrane semiconductor component having an outer region and a membrane region, the method comprising the following steps:
forming a first membrane semiconductor component and a second membrane semiconductor component on a common substrate, wherein each of the first membrane semiconductor component and the second membrane semiconductor component includes a membrane region and an outer region disposed between the first membrane semiconductor component and the second membrane semiconductor component, wherein the substrate is structured such that a respective first backside cavity is configured in the membrane region of the first membrane semiconductor component and in the membrane region of the second membrane semiconductor component, wherein the first backside cavity is free of the substrate, and wherein at least one respective active region is configured in the membrane region of the first membrane semiconductor component and in the membrane region of the second membrane semiconductor component, and the active region includes at least one control electrode;
forming a target separation point which includes a second backside cavity in the outer region between the first membrane semiconductor component and the second membrane semiconductor component, wherein the second backside cavity is free of the substrate; and
separating the target separation point such that the first membrane semiconductor component and the second membrane semiconductor component are separated from one another.

25. The method according to claim 24, wherein the separation of the target separation point is carried out using a saw.

26. The method according to claim 24, wherein the separation of the target separation point is carried out by breaking one or more layers of the target separation point, using a lateral expansion of the target separation point or using a pressure difference at the target separation point.

27. The method according to claim 24, wherein the separation of the target separation point is carried out by an etching process, including a wet chemical etching process or a dry chemical etching process, such that one or more layers on or above the second backside cavity are removed by the etching process.
